(19) United States
(12) Patent Application Publication
(10) Pub. No.: US 2022/0180953 A1
(43) Pub. Date: Jun. 9, 2022

(54) STORAGE DEVICE AND OPERATING METHOD THEREOF

(71) Applicant: SK hynix Inc., Icheon-si (KR)

(72) Inventors: Chung Un NA, Icheon-si (KR); Yang Hyeon KWON, Icheon-si (KR)

(21) Appl. No.: 17/344,264

(22) Filed: Jun. 10, 2021

(30) Foreign Application Priority Data
Dec. 4, 2020 (KR) 10-2020-0168797

(51) Int. Cl. G11C 16/34; G11C 16/10; G11C 16/24; G11C 16/08; G11C 16/26

(52) U.S. Cl. CPC G11C 16/3486; G11C 16/3404; G11C 16/26; G11C 16/24; G11C 16/08; G11C 16/102

(57) ABSTRACT

A storage device includes: a memory device including a plurality of memory cells configured to store data and a plurality of word lines connected to the plurality of memory cells and a memory controller in communication with the memory device and configured to control the memory device, including controlling the memory device to perform a read operation perform, upon a failure of the read operation on the memory cell, a read retry operation by changing the read voltage based on a history read table, and wherein the memory controller is further configured to update the history read table, upon a success of the read retry operation, based on whether the word line connected to the memory cell is a last programmed word line according to a program order among word lines connected to the group of memory cells.

### CROSS-REFERENCE TO RELATED APPLICATION

This patent document claims priority to and benefits of the Korean patent application number 10-2020-0168797, filed Dec. 4, 2020, which is incorporated herein by reference in its entirety.

### TECHNICAL FIELD

The technology and implementations disclosed in this patent document generally relates to an electronic device, and more particularly, to a storage device and an operating method thereof.

### BACKGROUND

Storage devices refer to electronic components that are configured to store data on a permanent or temporary basis. Each storage device may include one or more storage medium to store data and operate based on a request from a host device such as a computer or a smart phone. The storage device may include a storage medium for storing data and may further include a memory controller for controlling storage medium to store or retrieve data. The memory device used as a storage medium is classified into a volatile memory device and a nonvolatile memory device.

A volatile memory device may store data only when power is supplied. Thus, such a volatile memory device loses its data in the absence of power. The volatile memory device may include a Static Random Access Memory (SRAM), a Dynamic Random Access Memory (DRAM), or others.

The nonvolatile memory device can retain its data in the absence of power. The nonvolatile memory device may include a Read Only Memory (ROM), a Programmable ROM (PROM), an Electrically Programmable ROM (EPROM), an Electrically Erasable ROM (EEROM), a flash memory, or others.

### SUMMARY

Embodiments provide a storage device for performing an improved read retry operation and an operating method of the storage device.

In one aspect, a storage device is provided to include a memory device including a plurality of word lines and a plurality of memory cells connected to the plurality of word lines, the memory device performing a read operation of reading data stored in the plurality of memory cells; and a memory controller configured to: when the read operation fails, change a level of a read voltage, based on a history read table, and control the memory device to perform a read retry operation of retrying the read operation by using the changed level of the read voltage; and when the read retry operation passes, update a first read voltage of the read retry operation which has passed in the history read table, wherein, when a target word line of the read retry operation is a word line corresponding to last programmed memory cells among word lines corresponding to a target block of the read operation, the memory controller updates the history read table, based on a result obtained by comparing the first read voltage with a second read voltage pre-stored in the history read table.

In another aspect, a storage device is provided to include: a memory device including a plurality of memory cells configured to store data and a plurality of word lines connected to the plurality of memory cells and a memory controller in communication with the memory device and configured to control the memory device, including controlling the memory device to (1) perform a read operation on a group of memory cells using a read voltage on a memory cell and (2) perform, upon a failure of the read operation on the memory cell, a read retry operation to perform another read operation on the memory cell by changing the read voltage based on a history read table that is stored in at least one of the memory device or the memory controller and includes information on read voltages, and wherein the memory controller is further configured to update the history read table, upon a success of the read retry operation, based on whether the word line connected to the memory cell is a last programmed word line according to a program order among word lines connected to the group of memory cells.

In another aspect, a method is provided for operating a storage device including a plurality of word lines and a plurality of memory cells connected to the plurality of word lines. The method comprises: performing a read operation of reading data stored in the plurality of memory cells by using a target word line among the plurality of word lines; when the read operation fails, changing a level of a read voltage, based on a history read table, and performing a read retry operation of retrying the read operation by using the changed level of the read voltage; and when the read retry operation passes, updating a first read voltage of the read retry operation which has passed in the history read table, wherein, in the updating, the history read table is updated based on a result obtained by comparing the first read voltage with a second read voltage pre-stored in the history read table, when the target word line is a word line corresponding to last programmed memory cells among word lines corresponding to a target block of the read operation.

In another aspect, a method for operating a storage device is provided. The method includes: performing a read operation on a group of memory cells using a read voltage to read data from a memory cell of the group, performing, upon a failure of the read operation on the memory cell, a read retry operation to perform another read operation on the memory cell by changing the read voltage based on a history read table that includes information on read voltages, checking, upon a success of the read retry operation on the memory cell, whether the word line connected to the memory cell is a last programmed word line according to a program order among word lines connected to the group of memory cells and updating the history read table or skipping updating of the read retry operation based on the checking.

### BRIEF DESCRIPTION OF THE DRAWINGS

Example embodiments will now be described more fully hereinafter with reference to the accompanying drawings.

FIG. 1 is a block diagram illustrating a storage device in accordance with an embodiment of the disclosed technology.

FIG. 2 is a block diagram illustrating a memory device in accordance with an embodiment of the disclosed technology.

FIG. 3 is a diagram illustrating a memory block in accordance with an embodiment of the disclosed technology.

FIG. 4 is a diagram illustrating a memory block in accordance with an embodiment of the disclosed technology.

FIG. 5 is a diagram illustrating a memory block in accordance with an embodiment of the disclosed technology.

FIG. 6 is a diagram illustrating a program state of a memory cell in accordance with an embodiment of the disclosed technology.

FIG. 7 is a diagram illustrating a read operation in accordance with an embodiment of the disclosed technology.

FIG. 8 is a diagram illustrating an interference phenomenon occurring between word lines in accordance with an embodiment of the disclosed technology.

FIG. 9 is a diagram illustrating program states of memory cells corresponding to word lines in accordance with an embodiment of the disclosed technology.

FIG. 10 is a diagram illustrating an open block and a last programmed word line in accordance with an embodiment of the disclosed technology.

FIG. 11 is a flowchart illustrating an operating method of the storage device in accordance with an embodiment of the disclosed technology.

FIG. 12 is a diagram illustrating a memory controller in accordance with an embodiment of the disclosed technology.

FIG. 13 is a diagram illustrating a memory controller in accordance with another embodiment of the disclosed technology.

FIG. 14 is a diagram illustrating a memory card system in accordance with an embodiment of the disclosed technology.

FIG. 15 is a diagram illustrating a Solid State Drive (SSD) in accordance with an embodiment of the disclosed technology.

FIG. 16 is a diagram illustrating a user system in accordance with an embodiment of the disclosed technology.

### DETAILED DESCRIPTION

The specific structural or functional description disclosed herein is merely illustrative for the purpose of describing embodiments according to the concept of the disclosed technology. The embodiments according to the concept of the disclosed technology can be implemented in various forms, and cannot be construed as limited to the embodiments set forth herein.

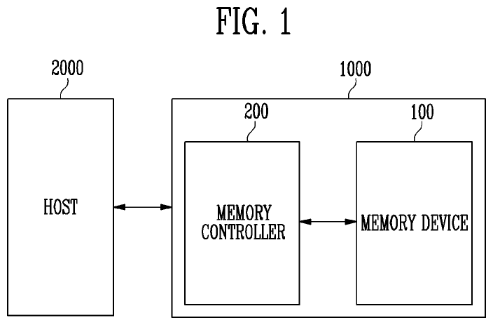

FIG. 1 is a block diagram illustrating a storage device in accordance with an embodiment of the disclosed technology.

Referring to FIG. 1, the storage device 1000 may include a memory device 100 and a memory controller 200.

The storage device 1000 may be a device for storing data under the control of a host 2000, such as a mobile phone, a smart phone, an MP3 player, a laptop computer, a desktop computer, a game console, a display device, a tablet PC or an in-vehicle infotainment.

The storage device 1000 may be manufactured as any one of various types of storage devices according to a host interface that is a communication interface between the host 2000 and the storage device 1000. For example, the storage device 1000 may be implemented with any one of a variety of types of storage devices, such as a Solid State Drive (SSD), a Multi-Media Card (MMC), an Embedded MMC (eMMC), a Reduced Size MMC (RS-MMC), a micro-MMC (micro-MMC), a Secure Digital (SD) card, a mini-SD card, a micro-SD card, a Universal Serial Bus (USB) storage device, a Universal Flash Storage (UFS) device, a Compact Flash (CF) card, a Smart Media Card (SMC), a memory stick, and the like.

The storage device 1000 may be implemented as any one of various kinds of package types. For example, the storage device 1000 may be implemented as any one of various kinds of package types such as a Package-On-Package (POP), a System-In-Package (SIP), a System-On-Chip (SOC), a Multi-Chip Package (MCP), a Chip-On-Board (COB), a Wafer-level Fabricated Package (WFP), or a Wafer-level Stack Package (WSP).

The memory device 100 may store data or use stored data. The memory device 100 operates based on the control of the memory controller 200. Also, the memory device 100 may include a plurality of memory dies, and each of the plurality of memory dies may include a memory cell array including a plurality of memory cells for storing data.

Each of the memory cells may be configured as a Single Level Cell (SLC) storing one data bit, a Multi-Level Cell (MLC) storing two data bits, a Triple Level Cell (TLC) storing three data bits, or a Quad Level Cell (QLC) storing four data bits.

The memory cell array may include a plurality of memory blocks. The memory capacity of the memory cell array is dictated by the number of memory cells, the smallest storage units in the memory cell array. The memory cells may be grouped into different groups in performing memory operations such as reading and writing data. In various applications, the grouping of memory cells may be organized in pages and blocks, where the memory cells are grouped as pages of memory cells and each page includes multiple memory cells. Such pages of memory cells may be further grouped into blocks of memory pages where one memory block may include a plurality of pages. In some implementations, an operation for storing data in the memory device 100 or reading data stored in the memory device 100 may be performed on a page basis by reading data from or writing data into memory cells one page at a time.

The memory device 100 may be implemented as a Double Data Rate Synchronous Dynamic Random Access Memory (DDR SDRAM), a Low Power Double Data Rate 4 (LPDDR4) SDRAM, a Graphics Double Data Rate (GDDR) SRAM, a Low Power DDR (LPDDR), a Rambus Dynamic Random Access Memory (RDRAM), a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or others. In this patent document, some implementations maybe explained assuming that the memory device 100 is a NAND flash memory but other implementations are also possible.

The memory device 100 may receive a command and an address from the memory controller 200. The memory device 100 may access an area selected by the received address in the memory cell array. That the memory device 100 accesses the selected area may mean that the memory device 100 performs an operation corresponding to the received command on the selected area. For example, the memory device 100 may perform a write operation (program operation), a read operation, and an erase operation. The program operation may be an operation in which the memory device 100 records data in the area selected by the address. The read operation may mean an operation in which the memory device 100 reads data from the area selected by the address. The erase operation may mean an operation in which the memory device 100 erases data stored in the area selected by the address.

The memory controller 200 may control overall operations of the storage device 1000. Specifically, when power is applied to the storage device 1000, the memory controller 200 may execute firmware (FW). The FW may include a Host Interface Layer (HIL) which receives a request input from the host 2000 or outputs a response to the host 2000, a Flash Translation Layer (FTL) which manages an operation between an interface of the host 2000 and an interface of the memory device 100, and a Flash Interface Layer (FIL) which provides a command to the memory device 100 or receives a response from the memory device 100.

The memory controller 200 may receive data and a Logical Address (LA) from the host 2000, and translate the LA into a Physical Address (PA) representing an address of memory cells in which data included in the memory device 100 is to be stored. The LA may be a Logical Block Address (LBA), and the PA may be a Physical Block Address (PBA).

The memory controller 200 may control the memory device 100 to perform a program operation, a read operation, an erase operation, or the like in response to a request from the host 2000. In the program operation, the memory controller 200 may provide a program command, a PBA, and data to the memory device 100. In the read operation, the memory controller 200 may provide a read command and a PBA to the memory device 100. In the erase operation, the memory controller 200 may provide an erase command and a PBA to the memory device 100.

In accordance with an embodiment of the disclosed technology, the memory controller 200 may control the memory device 100 to perform a read operation according to a read request of the host 2000. Also, when the read operation fails, the memory controller 200 may control the memory device 100 to perform a read retry operation of retrying the read operation by changing a level of a read voltage.

The memory controller 200 may control the memory device 100 to autonomously perform a program operation, a read operation, or an erase operation regardless of any requests from the host 2000. For example, the memory controller 200 may control the memory device 100 to perform a program operation, a read operation, or an erase operation, which is used to perform a background operation such as wear leveling, garbage collection, or read reclaim.

The host 2000 may communicate with the storage device 1000, using at least one of various communication manners, such as a Universal Serial bus (USB), a Serial AT Attachment (SATA), a High Speed InterChip (HSIC), a Small Computer System Interface (SCSI), Firewire, a Peripheral Component Interconnection (PCI), a PCI express (PCIe), a Non-Volatile Memory express (NVMe), a universal flash storage (UFS), a Secure Digital (SD), a Multi-Media Card (MMC), an embedded MMC (eMMC), a Dual In-line Memory Module (DIMM), a Registered DIMM (RDIMM), and a Load Reduced DIMM (LRDIMM).

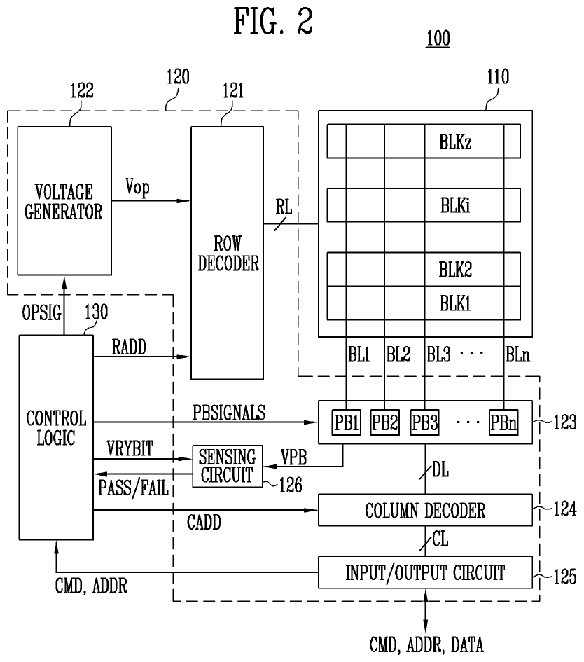

FIG. 2 is a block diagram illustrating a memory device in accordance with an embodiment of the disclosed technology.

Referring to FIG. 2, the memory device 100 may include a memory cell array 110, a peripheral circuit 120, and a control logic 130.

The memory cell array 110 includes a plurality of memory blocks BLK1 to BLKz. The plurality of memory blocks BLK1 to BLKz are connected to a row decoder 121 through row lines RL. The row lines RL may include at least one source select line, a plurality of word lines, and at least one drain select line. The plurality of memory blocks BLK1 to BLKz are connected to a page buffer group 123 through bit lines BL1 to BLn. Each of the plurality of memory blocks BLK1 to BLKz includes a plurality of memory cells. In an embodiment, the plurality of memory cells may be nonvolatile memory cells. Memory cells connected to the same word line may be defined as one page. Therefore, one memory block may include a plurality of pages.

Each of the memory cells included in the memory cell array 110 may be configured as a Single Level Cell (SLC) storing one data bit, a Multi-Level Cell (MLC) storing two data bits, a Triple Level Cell (TLC) storing three data bits, or a Quadruple Level Cell (QLC) storing four data bits.

The peripheral circuit 120 may be configured to perform a program operation, a read operation or an erase operation on a selected area of the memory cell array 110 under the control of the control logic 130. That is, the peripheral circuit 120 may drive the memory cell array 110 under the control of the control logic 130. For example, the peripheral circuit 120 may apply various operating voltages to the row lines RL and the bit lines BL1 to BLn or discharge the applied voltages under the control of the control logic 130.

Specifically, the peripheral circuit 120 may include the row decoder 121, a voltage generator 122, the page buffer group 123, a column decoder 124, an input/output circuit 125, and a sensing circuit 126.

The row decoder 121 may be connected to the memory cell array 110 through the row lines RL. The row lines RL may include at least one source select line, a plurality of word lines, and at least one drain select line. In an embodiment, the word lines may include normal word lines and dummy word lines. In an embodiment, the row lines RL may further include a pipe select line.

The row decoder 121 may operate under the control of the control logic 130. The row decoder 121 may receive a row address RADD from the control logic 130. Specifically, the row decoder 121 may decode the row address RADD. The row decoder 121 may select at least one memory block among the memory blocks BLK1 to BLKz according to the decoded address. Also, the row decoder 121 may select at least one word line of the selected memory block to apply voltages generated by the voltage generator 122 to the at least one word line WL according the decoded address.

For example, in a program operation, the row decoder 121 may apply a program voltage to the selected word line, and apply a program pass voltage having a level lower than that of the program voltage to unselected word lines. In a program verify operation, the row decoder 121 may apply a verify voltage to the selected word line, and apply a verify pass voltage higher than the verify voltage to the unselected word lines. In a read operation, the row decoder 121 may apply a read voltage to the selected word line, and apply a read pass voltage higher than the read voltage.

In an embodiment, an erase operation of the memory device 100 may be performed in a memory block unit. In the erase operation, the row decoder 121 may select one memory block according to the decoded address. In the erase operation, the row decoder 121 may apply a ground voltage to word lines connected to the selected memory block.

The voltage generator 122 may operate under the control of the control logic 130. Specifically, the voltage generator 122 may generate a plurality of voltages by using an external power voltage supplied to the memory device 100 under the control of the control logic 130. For example, the voltage generator 122 may generate a program voltage, a verify voltage, a pass voltage, a read voltage, an erased voltage, and the like under the control of the control logic 130. That is, the voltage generator 122 may generate various operating voltages Vop used in program, read, and erase operations in response to an operation signal OPSIG.

In an embodiment, the voltage generator 122 may generate an internal power voltage by regulating the external power voltage. The internal power voltage generated by the voltage generator 122 may be used as an operation voltage of the memory cell array 110.

In an embodiment, the voltage generator 122 may generate a plurality of voltages by using the external power voltage or the internal power voltage. For example, the voltage generator 122 may include a plurality of pumping capacitors for receiving the internal power voltage, and generate the plurality of voltages by selectively activating the plurality of pumping capacitors under the control of the control logic 130. In addition, the plurality of generated voltages may be supplied to the memory cell array 110 by the row decoder 121.

The page buffer group 123 may include first to nth page buffers PB1 to PBn. The first to nth page buffers PB1 to PBn may be connected to the memory cell array 110 respectively through first to nth bit lines BL1 to BLn. Also, the first to nth bit lines BL1 to BLn may operate under the control of the control logic 130. Specifically, the first to nth bit lines BL1 to BLn may operate in response to page buffer control signals PBSIGNALS. For example, the first to nth page buffers PB1 to PBn may temporarily store data received through the first to nth bit lines BL1 to BLn, or sense a voltage or current of the bit lines BL1 to BLn in a read or verify operation.

Specifically, in a program operation, the first to nth page buffers PB1 to PBn may transfer data DATA received through the input/output circuit 125 to selected memory cells through the first to nth bit lines BL1 to BLn, when a program voltage is applied to a selected word line. Memory cells of a selected page may be programmed according to the transferred data DATA. A memory cell connected to a bit line to which a program allow voltage (e.g., a ground voltage) is applied may have an increased threshold voltage. A threshold voltage of a memory cell connected to a bit line to which a program inhibit voltage (e.g., a power voltage) is applied may be maintained.

In a program verify operation, the first to nth page buffers PB1 to PBn may read page data from the selected memory cells through the first to nth bit lines BL1 to BLn.

In a read operation, the first to nth page buffers PB1 to PBn may read data DATA from the memory cells of the selected page through the first to nth bit lines BL1 to BLn, and outputs the read data DATA to the input/output circuit 125 under the control of the column decoder 124.

In an erase operation, the first to nth page buffers PB1 to PBn may float the first to nth bit lines BL1 to BLn.

The column decoder 124 may communicate data between the input/output circuit 125 and the page buffer group 123 in response to a column address CADD. For example the column decoder 124 may communicate data with the first to nth page buffers PB1 to PBn through data lines DL, or communicate data with the input/output circuit 125 through column lines CL.

The input/output circuit 125 may transfer a command CMD and an address ADDR, which are received from the memory controller 200, to the control logic 130, or exchange data DATA with the column decoder 124.

In a read operation or verify operation, the sensing circuit 126 may generate a reference current in response to an allow bit VRYBIT signal, and output a pass PASS or a fail signal FAIL by comparing a sensing voltage VPB received from the page buffer group 123 and a reference voltage generated by the reference current.

The control logic 130 may control the peripheral circuit 120 by outputting the operation signal OPSIG, the row address RADD, the page buffer control signals PBSIGNALS, and the allow bit VRYBIT in response to the command CMD and the address ADDR.

Also, the control logic 130 may determine whether the verify operation has passed or failed in response to the pass or fail signal PASS or FAIL. Also, the control logic 130 may control the page buffer group 123 to temporarily store verify information including the pass or fail signal PASS or FAIL in the page buffer group 123. Specifically, the control logic 130 may determine a program state of a memory cell in response to the pass or fail signal PASS or FAIL. For example, when the memory cell operates as a Triple Level Cell (TLC), the control logic 130 may determine whether the program state of the memory cell is any one of an erase state E or first to seventh program states P1 to P7.

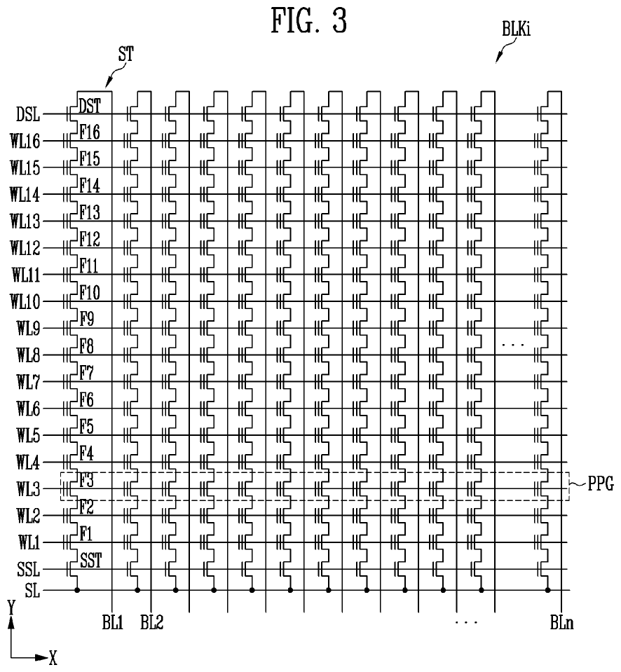

FIG. 3 is a diagram illustrating a memory block in accordance with an embodiment of the disclosed technology.

Referring to FIG. 3, in the memory block BLKi, a plurality of word lines arranged in parallel to each other may be connected between a first select line and a second select line. The first select line may be a source select line SSL, and the second select line may be a drain select line DSL. More specifically, the memory block BLKi may include a plurality of strings ST connected between bit lines BL1 to BLn and a source line SL. The bit lines BL1 to BLn may be respectively connected to the strings ST, and the source line SL may be commonly connected to the strings ST. The strings ST may be configured identically to one another, and therefore, a string ST connected to a first bit line BL1 will be described in detail as an example.

The string ST may include a source select transistor SST, a plurality of memory cells MC1 to MC16, and a drain select transistor DAT, which are connected in series to each other between the source line SL and the first bit line BL1. At least one source select transistor SST and at least one drain select transistor DST may be included in one string ST, and memory cells of which number is greater than that of the memory cells MC1 to MC16 shown in the drawing may be included in the one string ST.

A source of the source select transistor SST may be connected to the source line SL, and a drain of the drain select transistor DST may be connected to the first bit line BL1. The memory cells MC1 to MC16 may be connected in series between the source select transistor SST and the drain select transistor DST. Gates of source select transistors SST included in different strings ST may be connected to the source select line SSL, and gates of drain select transistors DST included in different strings ST may be connected to the drain select line DSL. Gates of the memory cells MC1 to MC16 may be connected to a plurality of word lines WL1 to WL16. A group of memory cells connected to the same word line among memory cells included in different strings ST may be referred to as a physical page PPG. Therefore, physical pages PPG corresponding to the number of the word lines WL1 to WL16 may be included in the memory block BLKi.

Each of the memory cells may be configured as a Single Level Cell (SLC) storing one data bit, a Multi-Level Cell (MLC) storing two data bits, a Triple Level Cell (TLC) storing three data bits, or a Quad Level Cell (QLC) storing four data bits.

The SLC may store one-bit data. One physical page PG of the SLC may store one logical page (LPG) data. The one LPG data may include data bits of which number corresponding to that of cells included in the one physical page PG.

The MLC, the TLC, and the QLC may store two or more-bit data. One physical page PG may store two or more LPG data.

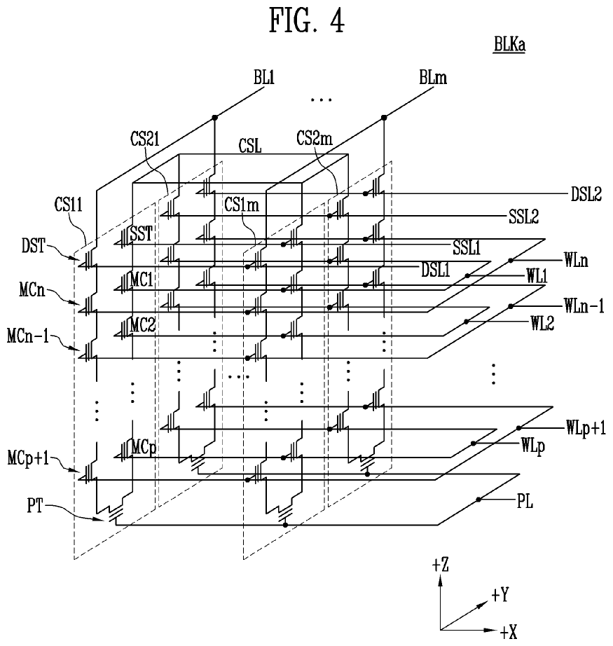

FIG. 4 is a diagram illustrating a super block in accordance with an embodiment of the disclosed technology.

Referring to FIG. 4, each of a plurality of super blocks Super Block 1 to Super Block N may include a plurality of memory blocks BLK. For example, each of first to Nth super blocks Super Block 1 to Super Block N may include a plurality of memory blocks. Numbers of memory blocks respectively included in the plurality of super blocks Super Block 1 to Super Block N may be the same. Alternatively, in accordance with an embodiment, numbers of memory blocks respectively included in the plurality of super blocks Super Block 1 to Super Block N may be different from each other according to an operation unit.

Specifically, the storage device 1000 may perform an internal operation in units of super blocks. For example, the memory controller 200 may control the memory device 100 to store data in units of super blocks. The memory controller 200 may control the memory device 100 to store consecutive logical addresses in one super block. Also, the memory controller 200 may map logical addresses and physical addresses in units of super blocks.

In accordance with an embodiment of the disclosed technology, each of the plurality of super blocks Super Block 1 to Super Block N may correspond to a bitmap to which N bits are allocated. For example, each memory block may correspond to a bitmap to which four bits are allocated per memory block. That is, in each of the plurality of super blocks Super Block 1 to Super Block N included in the memory device 100, each of the plurality of memory blocks may correspond to a bitmap to which four bits are allocated.

FIG. 4 is a diagram illustrating a memory block in accordance with an embodiment of the disclosed technology.

Referring to FIG. 4, any one memory block BLKa among the memory blocks BLK1 to BLKz shown in FIG. 2 is illustrated. The memory block BLKa may include a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings may be arranged in a row direction (i.e., a +X direction).

Meanwhile, although a case two cell strings arranged in a column direction (i.e., a +Y direction) is illustrated in FIG. 4, this is for convenience of description, and it will be apparent that three cell strings may be arranged in the column direction.

Each of the plurality of cell strings CS11 to CS1m and CS21 to CS2m may include at least one source select transistor SST, first to nth memory cells MC1 to MCn, a pipe transistor PT, and at least one drain select transistor DST.

The select transistors SST and DST and the memory cells MC1 to MCn may have structures similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is connected between a common source line CSL and memory cells MC1 to MCp.

In an embodiment, the source select transistors of cell strings arranged on the same row are connected to a source select line extending in the row direction, and the source select transistors of cell strings arranged on different rows are connected to different source select lines. Referring to FIG. 4, the source select transistors of the cell strings CS11 to CS1m on a first row are connected to a first source select line SSL1. The source select transistors of the cell strings CS21 to CS2m on a second row are connected to a second source select line SSL2.

In another embodiment, the source select transistors of the cell strings CS11 to CS1m and CS21 to CS2m may be commonly connected to one source select line.

The first to nth memory cells MC1 to MCn of each cell string may be connected between the source select transistor SST and the drain select transistor DST.

The first to nth memory cells MC1 to MCn may be divided into first to pth memory cells MC1 to MCp and a (p+1)th to nth memory cells MCp+1 to MCn. The first to pth memory cells MC1 to MCp may be sequentially arranged in the opposite direction of a +Z direction, and be connected in series between the source select transistor SST and the pipe transistor PT. The (p+1)th to nth memory cells MCp+1 to MCn may be sequentially arranged in the +Z direction, and be connected in series between the pipe transistor PT and the drain select transistor DST. The first to pth memory cells MC1 to MCp and the (p+1)th to nth memory cells MCp+1 to MCn are connected through the pipe transistor PT. Gate electrodes of the first to nth memory cells MC1 to MCn of each cell string may be connected to first to nth word lines WL1 to WLn, respectively.

A gate of the pipe transistor PT of each cell string may be connected to a pipe line PL.

The drain select transistor DST of each cell string may be connected between a corresponding bit line and the memory cells MCp+1 to MCn. Cell strings arranged in the row direction may be connected to a drain select line extending in the row direction. The drain select transistors of the cell strings CS11 to CS1m on the first row may be connected to a first drain select line DSL1. The drain select transistors of the cell strings CS21 to CS2m on the second row may be connected to a second drain select line DSL2.

Cell strings arranged in the column direction may be connected to a bit line extending in the column direction. Referring to FIG. 4, the cell strings CS11 and CS21 on a first column may be connected to a first bit line BL1. The cell strings CS1m and CS2m on an mth column may be connected to an mth bit line BLm.

Memory cells connected to the same word line in the cell strings arranged in the row direction may constitute one page. For example, memory cells connected to the first word line WL1 in the cell strings CS11 to CS1m on the first row may constitute one page. Memory cells connected to the first word line WL1 in the cell strings CS21 to CS2m on the second row may constitute another page. As any one of the drain select lines DSL1 and DSL2 is selected, cell strings arranged in one row direction may be selected. As any one of the word lines WL1 to WLn is selected, one page may be selected in the selected cell strings.

In another embodiment, even bit lines and odd bit lines may be provided instead of the first to mth bit lines BL1 to BLm. In addition, even-numbered cell strings among the cell strings CS11 to CS1m or CS21 to CS2m arranged in the row direction may be connected to the even bit lines, respectively, and odd-numbered cell strings among the cell strings CS11 to CS1m or CS21 to CS2m arranged in the row direction may be connected to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. When the number of dummy memory cells increases, the reliability of an operation of the memory block BLKa is improved. On the other hand, the size of the memory block BLKa increases. When the number of dummy memory cells decreases, the size of the memory block BLKa decreases. On the other hand, the reliability of an operation of the memory block BLKa may be deteriorated.

In order to efficiently control the at least one dummy memory cell, the dummy memory cells may have a required threshold voltage. Before or after an erase operation of the memory block BLKa, a program operation may be performed on all or some of the dummy memory cells. When an erase operation is performed after the program operation is performed, the threshold voltage of the dummy memory cells control a voltage applied to the dummy word lines connected to the respective dummy memory cells, so that the dummy memory cells can have the required threshold voltage.

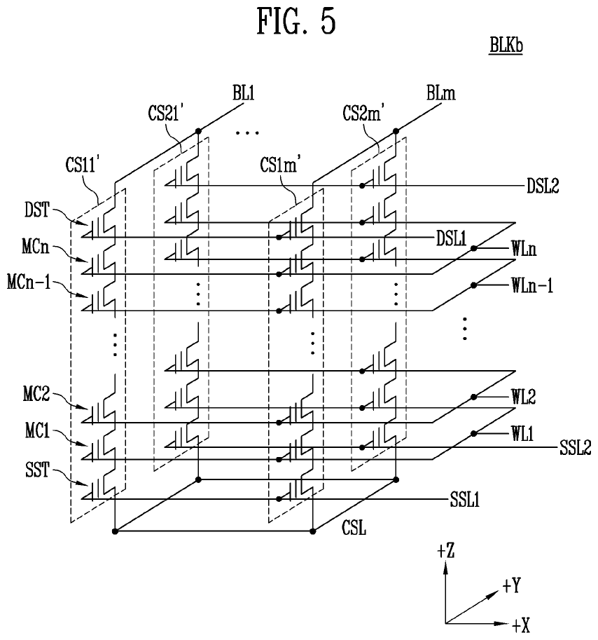

FIG. 5 is a diagram illustrating a memory block in accordance with an embodiment of the disclosed technology.

Referring to FIG. 5, another embodiment BLKb of the one memory block among the memory blocks BLK1 to BLKz shown in FIG. 2 is illustrated. The memory block BLKb may include a plurality of cell strings CS11′ to CS1m′ and CS21′ to CS2m′. Each of the plurality of cell strings CS11′ to CS1m′ and CS21′ to CS2m′ may extend along the +Z direction. Each of the plurality of cell strings CS11′ to CS1m′ and CS21′ to CS2m′ may include at least one source select transistor SST, first to nth memory cells MC1 to MCn, and at least one drain select transistor DST, which are stacked on a substrate (not shown) under the memory block BLKb.

The source select transistor SST of each cell string may be connected between a common source line CSL and the memory cells MC1 to MCn. The source select transistors of cell strings arranged on the same row may be connected to the same source select line. The source select transistors of the cell strings CS11′ to CS1m′ arranged on a first row may be connected to a first source select line SSL1. Source select transistors of the cell strings CS21′ to CS2m′ arranged on a second row may be connected to a second source select line 55L2. In another embodiment, the source select transistors of the cell strings CS11′ to CS1m′ and CS21′ to CS2m′ may be commonly connected to one source select line.

The first to nth memory cells MC1 to MCn of each cell string may be connected in series between the source select transistor SST and the drain select transistor DST. Gate electrodes of the first to nth memory cells MC1 to MCn may be connected to first to nth word lines WL1 to WLn, respectively.

The drain select transistor DST of each cell string may be connected between a corresponding bit line and the memory cells MC1 to MCn. The drain select transistors of cell strings arranged in the row direction may be connected to a drain select line extending in the row direction. The drain select transistors of the cell strings CS11′ to CS1m′ on the first row may be connected to a first drain select line DSL1. The drain select transistors of the cell strings CS21′ to CS2m′ on the second row may be connected to a second drain select line DSL2.

Consequently, the memory block BLKb of FIG. 5 may have a circuit similar to that of the memory block BLKa of FIG. 4, except that the pipe transistor PT is excluded from each cell string in FIG. 5.

In another embodiment, even bit lines and odd bit lines may be provided instead of the first to mth bit lines BL1 to BLm. In addition, even-numbered cell strings among the cell strings CS11′ to CS1m′ or CS21′ to CS2m′ arranged in the row direction may be connected to the even bit lines, respectively, and odd-numbered cell strings among the cell strings CS11′ to CS1m′ or CS21′ to CS2m′ arranged in the row direction may be connected to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. When the number of dummy memory cells increases, the reliability of an operation of the memory block BLKb is improved. On the other hand, the size of the memory block BLKb is increased. When the number of dummy memory cells decreases, the size of the memory block BLKb decreases. On the other hand, the reliability of an operation of the memory block BLKb may be deteriorated.

In order to efficiently control the at least one dummy memory cell, the dummy memory cells may have a required threshold voltage. Before or after an erase operation of the memory block BLKb, a program operation may be performed on all or some of the dummy memory cells. When an erase operation is performed after the program operation is performed, the threshold voltage of the dummy memory cells control a voltage applied to the dummy word lines connected to the respective dummy memory cells, so that the dummy memory cells can have the required threshold voltage.

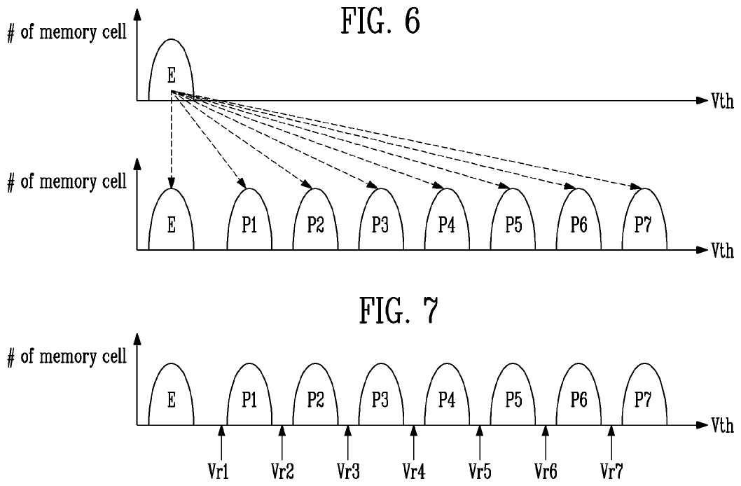

FIG. 6 is a diagram illustrating a program state of a memory cell in accordance with an embodiment of the disclosed technology.

Referring to FIG. 6, a memory cell may be programmed to one of an erase state E and first to seventh program states P1 to P7 according to a threshold voltage. Although the memory cell shown in FIG. 6 is illustrated as a Triple Level Cell (TLC) which can be programmed to one erase state and seven program states, this is an example only and other implementations are also possible. For example, the memory cell may be implemented as a Multi-Level Cell (MLC), a Single Level Cell (SLC), a Quad Level Cell (QLC), or the like. In this implementations, the erase state and the program states are distinguished from each other. In some other implementations, the erase state may be implemented as a zeroth program state P0. In this case, the erase state E and the first to seventh program states P1 to P7 may be expressed as the zeroth to seventh program states.

Memory cells connected to a selected word line may have a threshold voltage included in any one state among the erase state E and the first to seventh program states P1 to P7. Thus, the memory cells may be programmed to have a threshold voltage included in any one state among the erase state E and the first to seventh program states P1 to P7. The memory cells may be in the erase state E before a program operation is performed. In the program operation, the memory cells in the erase state E may be programmed to any one program state among the seven program states, when a program voltage is applied to the selected word line.

In some implementations, the erase state E and the first to seventh program state P1 to P7 of memory cells may be distinguished from each other by using read voltages.

FIG. 7 is a diagram illustrating a read operation in accordance with an embodiment of the disclosed technology.

Referring to FIG. 7, the erase state E and the first to seventh program states P1 to P7 may be distinguished from each other by using a plurality of read voltages.

The read operation may be an operation in which the memory device 100 reads data from an area selected by an address. The read operation may include a sensing operation of applying a read voltage to each memory cell, and identifying a status of the memory cell (e.g., whether the memory cell is an on-cell or off-cell) by checking a state of current flowing according to the applied read voltage.

In the sensing operation, the storage device 1000 may set a read voltage based on a threshold voltage value of memory cells, and may identify whether the memory cells are on-cells or off-cells by using the set read voltage. Specifically, in the erase state E and the first program state P1, memory cells may be divided into on cells and off cells by a first read voltage Vr1. In the first program state P1 and the second program state P2, memory cells may be divided into on cells and off cells by a second read voltage Vr2. In the second program state P2 and the third program state P3, memory cells may be divided into on cells and off cells by a third read voltage Vr3. In the third program state P3 and the fourth program state P4, memory cells may be divided into on cells and off cells by a fourth read voltage Vr4. In the fourth program state P4 and the fifth program state P5, memory cells may be divided into on cells and off cells by a fifth read voltage Vr5. In the fifth program state P5 and the sixth program state P6, memory cells may be divided into on cells and off cells by a sixth read voltage Vr6. In the sixth program state P6 and the seventh program state P7, memory cells may be divided into on cells and off cells by a seventh read voltage Vr7. That is, in the sensing operation, the storage device 1000 may identify whether the memory cell are on-cells or off-cells by setting the level of the read voltage to be higher than a maximum value of an on-cell distribution to be identified and setting the level of the read voltage to be lower than a minimum value of an off-cell distribution.

In addition, the read operation may include a decoding operation of identifying program states of a plurality of memory cells and converting a result of the decoding operation into data. In some implementations, the storage device 1000 may identify a state of a specific memory cell by applying the first to seventh read voltages Vr1 to Vr7 to the specific memory cell. For example, when the specific memory cell is programmed to the fourth program state P4, the specific memory cell may be sensed as an off-cell when the first to fourth read voltages Vr1 to Vr4 are applied to the specific memory cell, while the specific memory cell may be sensed as an on-cell when the fifth to seventh read voltages Vr5 to Vr7 are applied to the specific memory cell. Thus, the storage device 1000 may identify that the specific memory cell has been programmed to the fourth program state P4 by combining the sensed results. The storage device 1000 may identify program states of a plurality of memory cells in the same manner, and convert a distribution of the memory cells into data by combining the identified program states.

However, in the sensing operation, when a read voltage having a level at which a memory cell cannot be identified as on-cells or off-cells is applied, a read fail may occur and thus, the result of the read operation is not reliable. There are several circumstances to cause an occurrence of the read fail. For example, when a program operation is performed on memory cells adjacent to a specific memory cell, a threshold voltage distribution may be shifted by the programming of the memory cells, and a read fail may occur. In another example, when the read operation is performed on the memory cells that are adjacent to the specific memory cell and have been already programmed, if the level of a read voltage applied to a target word line is lower than the maximum value of the on-cell distribution or higher than the minimum value of the off-cell distribution, the read fail may occur.

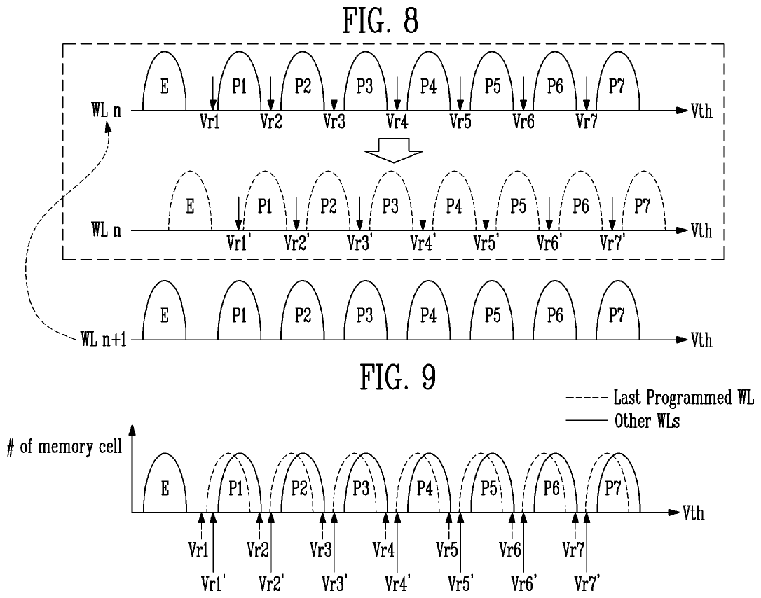

FIG. 8 is a diagram illustrating an interference phenomenon that occurs between word lines in accordance with an embodiment of the disclosed technology.

Referring to FIG. 8, a case where an interference phenomenon occurs in a target word line due to an adjacent word line is illustrated. The target word line may mean a word line corresponding to memory cells on which a read operation is to be performed, and an nth word line WLn and an (n+1)th word line WLn+1 may be word lines adjacent to each other.

First, memory cells respectively corresponding to the nth word line WLn and the (n+1)th word line may be in a state in which the memory cells are programmed to the first to seventh program states P1 to P7. In the example, after the memory cells corresponding to the nth word line WLn are first programmed, the memory cells corresponding to the (n+1)th word line WLn+1 may be programmed.

A threshold voltage of the memory cells corresponding to the nth word line WLn may be influenced by an interference phenomenon occurring due to a program operation performed on the (n+1)th word line WLn+1 and the memory cells corresponding to the (n+1)th word line WLn+1. Therefore, when the nth word line WLn is read after the memory cells corresponding to the (n+1)th word line WLn+1 are programmed, a read fail may occur in a read operation on the memory cells corresponding to the nth word line WLn due to a change in threshold voltages.

Thus, the read fail may occur due to an energy change of electrons stored in a floating gate (FG) of the nth word line WLn and current drop occurring after the memory cells corresponding to the (n+1)th word line WLn+1 are programmed.

The storage device 1000 may perform a read retry operation of retrying the read operation by applying a changed read voltage Vr′ to the target word line so as to address an interference phenomenon (e.g., Z-interference) occurring in the target word line due to the adjacent word line. For example, the storage device 1000 may distinguish the erase state E and the first program state P1 from each other by changing the level Vr1 of the first read voltage to a first level Vr1′. Similarly, the read operation may be performed by changing the levels Vr2 to Vr7 of the second to seventh read voltages to second to seventh levels Vr2′ to Vr7′.

FIG. 9 is a diagram illustrating program states of memory cells corresponding to word lines in accordance with an embodiment of the disclosed technology.

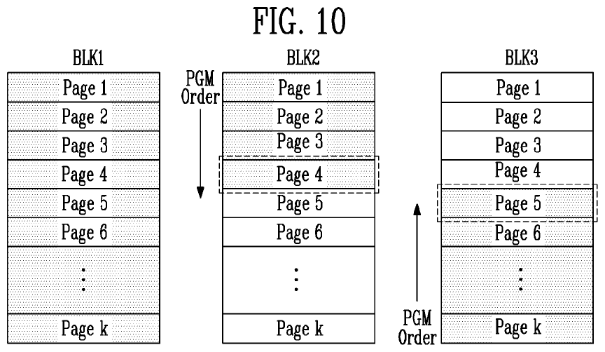

Referring to FIG. 9, a read voltage applied in a read operation performed on a last programmed word line and a read voltage applied in a read operation performed any other word lines are illustrated. In FIG. 9, it is assumed that the memory cells shown in FIG. 9 are included in a memory block that corresponds to an open block. As will be further discussed with reference to FIG. 10, the open block refers to the memory block in which only some of the memory cells included in the memory block are programmed.

A plurality of word lines may be connected to a target block on which a read operation is to be performed. In addition, the plurality of word lines connected to the target block may form different threshold voltage distributions due to an interference phenomenon between adjacent word lines as described in FIG. 8. Specifically, the interference phenomenon causes a threshold voltage distribution of a memory cell corresponding to the last programmed word line to shift as compared with other memory cells corresponding to other word lines than the last programmed word line. FIG. 9 shows that the memory cell corresponding to the last programmed word line has the threshold voltage distribution that is shifted to a left side along a horizontal axis as compared to that of the memory cell corresponding to other word lines. The last programmed word line refers to the word line that is programmed lastly according to the program order as will be further explained with regard to FIG. 10. Due to the left shifting of the threshold voltage distribution of the memory cell corresponding to the last programmed word line, a level of the read voltage used to sense a threshold voltage distribution corresponding to the last programmed word line may need to be lower than that of the read voltage used to sense a threshold voltage distribution corresponding to any other word lines.

Referring to FIG. 9, the level of the first read voltage that can distinguish the erase state E from the first program state P1 corresponding to the last programmed word line, which is Vr1, is lower than the level of the first read voltage corresponding to another word line, which is Vr1′. Based on this, the read voltage corresponding to the last programmed word line needs to be different from the read voltage corresponding to any other word line. Thus, when applying read voltages to a target word line, it needs to be considered whether the target word line is a last programmed word line or not.

In accordance with an embodiment of the disclosed technology, when a read fail occurs, the storage device 1000 may perform a read retry operation to perform a read operation by changing a level of a read voltage. The change of the read voltage for the read retry operation is made based on the history read table that is stored in the memory device and provides information on read voltages at which the read retry operation is to be performed for each of a plurality memory blocks included in the memory device 100.

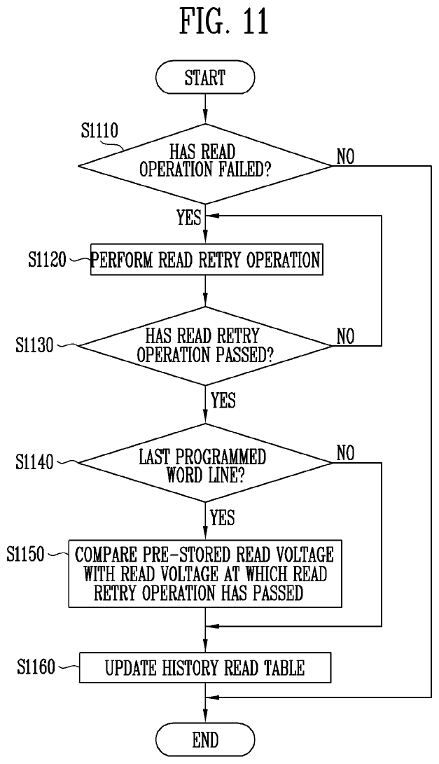

When the read retry operation passes, depending on whether the memory cell on which the read retry operation is connected to a last programmed word line or not, the read voltage used during the read retry operation may be updated in a history read table. As will be further discussed with reference to FIG. 11, once the read retry operation is successful, it is determined whether the memory cell on which the read retry operation corresponds to the last programmed memory cell. In case that the memory cell is connected to any word line other than the last programmed word line, the read voltage used during the read retry operation is updated in the history read table. In case that the memory cell is connected to the last programmed word line, the storage device 1000 may update the history read table based on a comparison result with a level of a read voltage pre-stored in the history read table. Specifically, when a difference between the level of the read voltage pre-stored in the history read table and the level of the read voltage at which the read retry operation has passed is smaller than a predetermined threshold value, the storage device 1000 may update the history read table. The predetermined threshold value may be experimentally determined with reference to a distance between program states. For example, the predetermined threshold value may be determined with reference to a distance between a maximum value of a threshold voltage level of the second program state P2 and a minimum value of a threshold voltage of the third program state P3. In addition, the history read table may store a read voltage at which the read retry operation is to be performed for each memory block.

FIG. 10 is a diagram illustrating an open block and a last programmed word line in accordance with an embodiment of the disclosed technology.

Referring to FIG. 10, first to third memory blocks BLK1 to BLK3 are illustrated. One memory block may include a plurality of pages. In addition, one page may include a plurality of memory cells. In addition, memory cells included in each page may be connected to the same word line. The page may be one unit for reading data stored in the memory device 100.

The second memory block BLK2 may include first to kth pages, and the third memory block BLK3 may include first to kth pages.

The first memory block BLK1 may be a close block. Specifically, the first memory block BLK1 may be in a state in which a plurality of pages are all programmed. For example, the first memory bock BLK1 may first to kth pages Page 1 to Page k, and the first to kth pages Page 1 to Page k included in the first memory block BLK1 are in a state in which the first to kth pages Page 1 to Page k are all programmed.

The second memory block BLK2 and the third memory block BLK3 may correspond to an open block. Specifically, the second memory block BLK2 and the third memory block BLK3 may be in a state in which only some memory cells among a plurality of memory cells included in each of the second memory block BLK2 and the third memory block BLK3 are programmed. For example, the second memory block BLK2 may be in a state in which only the first to fourth pages Page 1 to Page 4 included in the second memory block BLK2 are programmed. In addition, the third memory block BLK3 may be in a state in which only the fifth to kth pages Page 5 to Page k included in the third memory block BLK3 are programmed.

Positions of memory cells corresponding to the last programmed word line may be different from each other according to a program direction. Specifically, when a program operation is sequentially performed on pages from the first page Page 1, a page of which physical address is ranked last among programmed pages may be the last programmed page. When a program operation is performed in reverse order on the pages from the kth page Page k, a page of which physical address is ranked first may be the last programmed page.

For example, a page corresponding to the last programmed word line in the second memory block BLK2 may be the fourth page Page 4. In addition, a page corresponding to the last programmed word line in the third memory block BLK3 may be the fifth page Page 5.

FIG. 11 is a flowchart illustrating an operating method of a storage device in accordance with an embodiment of the disclosed technology.

Referring to FIG. 11, an operating method of the storage device 1000 including a plurality of word lines and a plurality of memory cells is illustrated.

The storage device 1000 may perform a read operation of reading stored data in response to a read request of the host 2000. Specifically, the storage device 1000 may perform a read operation of reading data stored in the plurality of memory cells by using a target word line among the plurality of word lines. The read operation may include a sensing operation of sensing the data stored in the plurality of memory cells and a decoding operation of decoding a result of the sensing operation.

Also, the storage device 1000 may determine whether the read operation has failed (S1110). When the read operation passes (S1110—NO), the storage device 1000 may transmit the data to the host 2000. When the read operation fails (S1110—YES), the storage device 1000 may perform a read retry operation (S1120). Specifically, the storage device 1000 may change a level of a read voltage, based on a history read table, and perform a read retry operation of retrying the read operation by using the changed level of the read voltage. The history read table may be a table for storing a read voltage at which the read retry operation is to be performed for each of a plurality memory blocks included in the memory device 100. Also, the history read table may be cached to the memory controller 200.

The read retry operation may include a decoding operation of changing a level of a read voltage, based on the history read table, performing a sensing operation by using the changed level of the read voltage, and decoding a result of the sensing operation.

Also, the storage device 1000 may determine whether the read retry operation has passed (S1130). When the read retry operation fails (S1130—NO), the storage device 1000 may retry the read retry operation by changing the level of the read voltage. When the read retry operation passes (S1130—YES), the storage device 1000 may determine whether the target word line is a last programmed word line among a plurality of word lines corresponding to a target block (S1140). The target word line or the target block may mean a word line or a memory block, which corresponds to memory cells on which the read retry operation or the read operation is to be performed. In addition, the target block may be an open block in which only some of memory cells corresponding to the target block are programmed.

When the target word line is the last programmed word line (S1140—YES), the storage device 1000 may compare a pre-stored read voltage with the read voltage at which the read retry operation has passed (S1150). The storage device 1000 may update the history read table, based on a result obtained by comparing the pre-stored read voltage with the read voltage at which the read retry operation has passed (S1160). For example, the read retry operation passes by using a first read voltage, the storage device 1000 may compare the first read voltage with a second read voltage that is pre-stored in the history read table. The storage device 1000 may update the history read table, based on a result obtained by comparing the first read voltage with the second read voltage. The storage device 1000 may determine whether the target word line is a word line corresponding to last programmed memory cells, based on a physical address of the memory device 100.

In some implementations, when a difference between voltage levels of the first read voltage and the second read voltage is smaller than a predetermined threshold value, the storage device 1000 may update the history read table.

In some implementations, when the target word line is not the last programmed word line (S1140—NO), the storage device 1000 may update the history read table by using the read voltage at which the read retry operation has passed (S1160). For example, when the read retry operation passes by using the first read voltage, the storage device 1000 may update the first read voltage in the history read table. Alternatively, when a decoding operation corresponding to the read retry operation passes, the storage device 1000 may update the first read voltage of the read retry operation in the history read table.

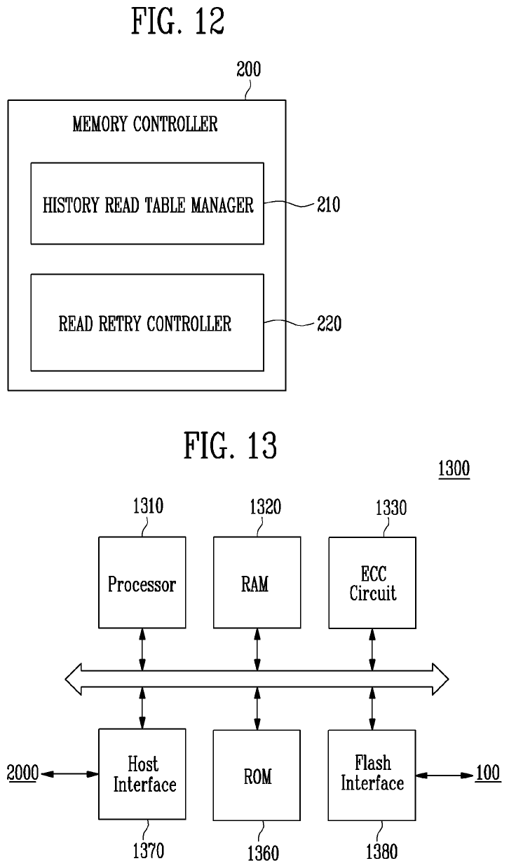

FIG. 12 is a diagram illustrating a memory controller in accordance with an embodiment of the disclosed technology.

Referring to FIG. 12, the memory controller 200 may include a history read table manager 210 and a read retry controller 220.

The history read table manager 210 may include a buffer memory (e.g., a DRAM, an SRAM, or the like). Also, the history read table manager 210 may store a history read table in the buffer memory. The history read table may be a table for storing a read voltage at which a read retry operation is to be performed for each of a plurality of memory blocks included in the memory device 100.

Also, the history read table manager 210 may update the stored history read table. Specifically, when a decoding operation corresponding to the read retry operation passes, the history read table manager 210 may update the read voltage at which the read retry operation has passed in the history read table. However, when the read retry operation which has passed is an operation on a last programmed word line, the history read table manager 210 may update the history read table, based on a result obtained by comparing a voltage level of the read voltage at which the read retry operation has passed with a voltage level of a pre-stored read voltage. Specifically, when a difference between the voltage level of the read voltage at which the read retry operation has passed and the voltage level of the pre-stored read voltage is smaller than a predetermined threshold value, the history read table manager 210 may update the history read table.

The read retry controller 220 may be a component for controlling the memory device 100 to perform a read retry operation. Specifically, when a read operation on a target word line fails, the read retry controller 220 may control the memory device 100 to perform the read retry operation on the target word line. The read retry operation may be an operation of retrying the read operation by changing a level of a read voltage applied to the target word line.

Also, the read retry controller 220 may control the memory device 100 to perform the read retry operation with reference to the history read table. The read retry controller 220 may control the memory device to perform a sensing operation by using the changed level of the read voltage and to perform a decoding operation of decoding a result of the sensing operation.

FIG. 13 is a diagram illustrating a memory controller in accordance with another embodiment of the disclosed technology.

Referring to FIG. 13, the memory controller 1300 may include a processor 1310, a RAM 1320, and an ECC circuit 1330, a ROM 1360, a host interface 1370, and a flash interface 1380. The memory controller 1300 shown in FIG. 13 may be an embodiment of the memory controller 200 shown in FIG. 12.

The processor 1310 may communicate with the host 2000 by using the host interface 1370, and perform a logical operation to control an operation of the memory controller 1300. For example, the processor 1310 may load a program command, a data file, a data structure, etc., based on a request received from the host 2000 or an external device, and perform various operations or generate a command and an address. For example, the processor 1310 may generate various commands necessary for a program operation, a read operation, an erase operation, a suspend operation, and a parameter setting operation.

Also, the processor 1310 may perform a function of a Flash Translation Layer (FTL). The processor 250 may translate a Logical Block Address (LBA) provided by the host 2000 into a Physical Block Address (PBA) through the FTL. The FTL may receive an LBA input by using a mapping table, to translate the LBA into a PBA. Several address mapping methods of the FTL exist according to mapping units. A representative address mapping method includes a page mapping method, a block mapping method, and a hybrid mapping method.

Also, the processor 1310 may generate a command without any request from the host 2000. For example, the processor 1310 may generate a command for background operations such as operations for wear leveling of the memory device 100 and operations for garbage collection of the memory device 100.

The RAM 1320 may be used as a buffer memory, a working memory, or a cache memory of the processor 1310. Also, the RAM 1320 may store codes and commands, which the processor 1310 executes. The RAM 1320 may store data processed by the processor 1310. Also, the RAM 1320 may be implemented, including a Static RAM (SRAM) or a Dynamic RAM (DRAM).

The ECC circuit 1330 may detect an error in a program operation or a read operation, and correct the detected error. Specifically, the ECC circuit 1330 may perform an error correction operation according to an Error Correction Code (ECC). Also, the ECC circuit 1330 may perform ECC encoding, based on data to be written to the memory device 100. The data on which the ECC encoding is performed may be transferred to the memory device 100 through the flash interface 1380. Also, the ECC circuit 1330 may perform ECC decoding on data received from the memory device 100 through the flash interface 1380.

The ROM 1360 may be used as a storage unit for storing various information necessary for an operation of the memory controller 1300. Specifically, the ROM 1360 may include a map table, and physical-to-logical address information and logical-to-physical address information may be stored in the map table. Also, the ROM 1360 may be controlled by the processor 1310.

The host interface 1370 may include a protocol for exchanging data between the host 2000 and the memory controller 1300. Specifically, the host interface 1370 may communicate with the host 2000 through at least one of various interface protocols such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, and a private protocol.

The flash interface 1380 may communicate with the memory device 100 by using a communication protocol under the control of the processor 1310. Specifically, the flash interface 1380 may communicate a command, an address, and data with the memory device 100 through a channel. For example, the flash interface 1380 may include a NAND interface.

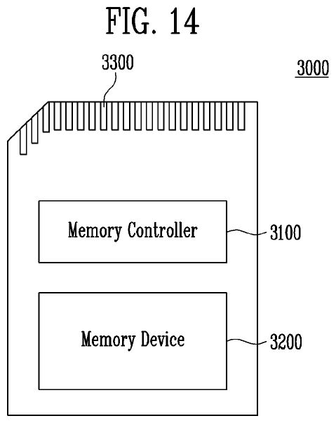

FIG. 14 is a diagram illustrating a memory card system in accordance with an embodiment of the disclosed technology.

Referring to FIG. 14, the memory card system 3000 includes a memory controller 3100, a memory device 3200, and a connector 3300.

The memory controller 3100 may be connected to the memory device 3200. The memory controller 3100 may access the memory device 3200. For example, the memory controller 3100 may control read, write, erase, and background operations on the memory device 3200. The memory controller 3100 may provide an interface between the memory device 3200 and a host. Also, the memory controller 3100 may drive firmware for controlling the memory device 3200.

For example, the memory controller 3100 may include components such as a Random Access Memory (RAM), a processing unit, a host interface, a memory interface, and the error corrector 233.

The memory controller 3100 may communicate with an external device through the connector 3300. The memory controller 3100 may communicate with the external device (e.g., the host) according to a specific communication protocol. Exemplarily, the memory controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe.

Exemplarily, the memory device 3200 may be implemented with various nonvolatile memory devices such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), and a Spin Torque Transfer magnetic RAM (STT-MRAM).

The memory controller 3100 and the memory device 3200 may be integrated into a single semiconductor device, to constitute a memory card. For example, the memory controller 3100 and the memory device 3200 may constitute a memory card such as a PC card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

FIG. 14 is a diagram illustrating a memory card system in accordance with an embodiment of the disclosed technology.

Referring to FIG. 14, the memory card system 3000 includes a memory controller 3100, a memory device 3200, and a connector 3300.

The memory controller 3100 may be connected to the memory device 3200. The memory controller 3100 may access the memory device 3200. For example, the memory controller 3100 may control read, write, erase, and background operations on the memory device 3200. The memory controller 3100 may provide an interface between the memory device 3200 and a host. Also, the memory controller 3100 may drive firmware for controlling the memory device 3200.

For example, the memory controller 3100 may include components such as a Random Access Memory (RAM), a processing unit, a host interface, a memory interface, and the error corrector 233.

The memory controller 3100 may communicate with an external device through the connector 3300. The memory controller 3100 may communicate with the external device (e.g., the host) according to a specific communication protocol. Exemplarily, the memory controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe.

Exemplarily, the memory device 3200 may be implemented with various nonvolatile memory devices such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), and a Spin Torque Transfer magnetic RAM (STT-MRAM).

The memory controller 3100 and the memory device 3200 may be integrated into a single semiconductor device, to constitute a memory card. For example, the memory controller 3100 and the memory device 3200 may constitute a memory card such as a PC card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

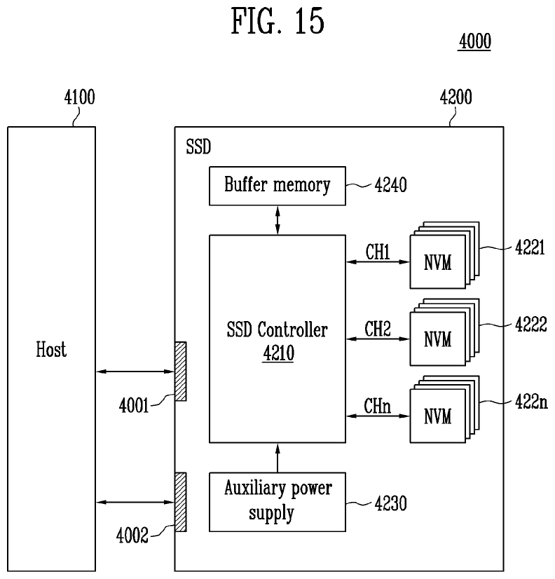

FIG. 15 is a diagram illustrating a Solid State Drive (SSD) in accordance with an embodiment of the disclosed technology.

Referring to FIG. 15, the SSD system 4000 includes a host 4100 and an SSD 4200. The SSD 4200 exchanges a signal SIG with the host 4100 through a signal connector 4001, and receives power PWR through a power connector 4002. The SSD 4200 includes an SSD controller 4210, a plurality of flash memories 4221 to 422n, an auxiliary power supply 4230, and a buffer memory 4240.

In an embodiment, the SSD controller 4210 may serve as the memory controller 200 described with reference to FIG. 1. The SSD controller 4210 may control the plurality of flash memories 4221 to 422n in response to a signal SIG received from the host 4100. Exemplarily, the signal SIG may be a signal based on an interface between the host 4100 and the SSD 4200. For example, the signal SIG may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. Exemplarily, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of flash memories 4221 to 422n, or temporarily store meta data (e.g., a mapping table) of the flash memories 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

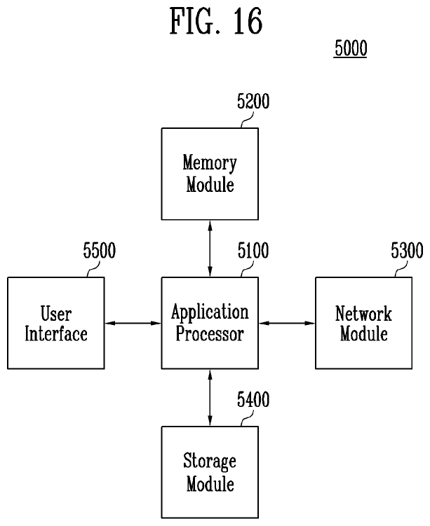

FIG. 16 is a diagram illustrating a user system in accordance with an embodiment of the disclosed technology.

Referring to FIG. 16, the user system 5000 includes an application processor 5100, a memory module 5200, a network module 5300, a storage module 5400, and a user interface 5500.

The application processor 5100 may drive components included in the user system 5000, an operating system (OS), a user program, or the like. Exemplarily, the application processor 5100 may include controllers for controlling components included in the user system 5000, interfaces, a graphic engine, and the like. The application processor 5100 may be provided as a System-on-Chip (SoC).

The memory module 5200 may operate as a main memory, working memory, buffer memory or cache memory of the user system 5000. The memory module 5200 may include volatile random access memories such as a DRAM, an SDRAM, a DDR SDRAM, a DDR2 SDRM, a DDR3 SDRAM, an LPDDR SDRAM, an LPDDR2 SDRAM, and an LPDDR3 SDRAM or nonvolatile random access memories such as a PRAM, a ReRAM, an MRAM, and a FRAM. Exemplarily, the application processor 5100 and the memory module 5200 may be provided as one semiconductor package by being packaged based on a Package on Package (PoP).

The network module 5300 may communicate with external devices. Exemplarily, the network module 5300 may support wireless communications such as Code Division Multiple Access (CDMA), Global System for Mobile communication (GSM), Wideband CDMA (WCDMA), CDMA-2000, Time Division Multiple Access (TDMA), Long Term Evolution (LTE), Wimax, WLAN, UWB, Bluetooth, and Wi-Fi. Exemplarily, the network module 5300 may be included in the application processor 5100.

The storage module 5400 may store data. For example, the storage module 5400 may store data received from the application processor 5100. Alternatively, the storage module 5400 may transmit data stored therein to the application processor 5100. Exemplarily, the storage module 5400 may be implemented with a nonvolatile semiconductor memory device such as a Phase-change RAM (PRAM), a Magnetic RAM (MRAM), a Resistive RAM (RRAM), a NAND flash, a NOR flash, or a NAND flash having a three-dimensional structure. Exemplarily, the storage module 5400 may be provided as a removable drive such as a memory card of the user system 5000 or an external drive.

Exemplarily, the storage module 5400 may include a plurality of nonvolatile memory devices, and the plurality of nonvolatile memory devices may operate identically to the memory device 100 described with reference to FIG. 1. The storage module 4400 may operate identically to the storage device 1000 described with reference to FIG. 1.

The user interface 5500 may include interfaces for inputting data or commands to the application processor 5100 or outputting data to an external device. Exemplarily, the user interface 5500 may include user input interfaces such as a keyboard, a keypad, a button, a touch panel, a touch screen, a touch pad, a touch ball, a camera, a microphone, a gyroscope sensor, a vibration sensor and a piezoelectric element. The user interface 4500 may include user output interfaces such as a Liquid Crystal Display (LCD), an Organic Light Emitting Diode (OLED) display device, an Active Matrix OLED (AMOLED) display device, an LED, a speaker, and a monitor.

In accordance with the disclosed technology, there can be provided a storage device for performing an improved read retry operation and an operating method of the storage device.

While the disclosed technology has been shown and described with reference to certain exemplary embodiments thereof, it will be understood by those skilled in the art that various changes in form and details may be made therein without departing from the spirit and scope of the disclosed technology as defined by the appended claims and their equivalents. Therefore, the scope of the disclosed technology should not be limited to the above-described exemplary embodiments but should be determined by not only the appended claims but also the equivalents thereof.

Only exemplary embodiments of the disclosed technology have been described in the drawings and specification. Various modifications and enhancements to the disclosed embodiments and other embodiments can be made based on what is described or/and illustrated in this patent document.

What is claimed is:

1. A storage device, comprising:
a memory device including a plurality of memory cells configured to store data and a plurality of word lines connected to the plurality of memory cells; and
a memory controller in communication with the memory device and configured to control the memory device, including controlling the memory device to (1) perform a read operation on a group of memory cells using a read voltage on a memory cell and (2) perform, upon a failure of the read operation on the memory cell, a read retry operation to perform another read operation on the memory cell by changing the read voltage based on a history read table that is stored in at least one of the memory device or the memory controller and includes information on read voltages, and
wherein the memory controller is further configured to update the history read table, upon a success of the read retry operation, based on whether the word line connected to the memory cell is a last programmed word line according to a program order among word lines connected to the group of memory cells.

2. The storage device of claim 1, wherein the memory controller is further configured to update the history read table with a changed read voltage in case that the word line connected to the memory cell is not the last programmed word line.

3. The storage device of claim 1, wherein, in case that the word line connected to the memory cell is the last programmed word line, the memory controller is further configured to compare a changed read voltage with a pre-stored read voltage that is included in the history read table for use for the read retry operation for the memory cell.

4. The storage device of claim 1, wherein the memory controller includes:
a history read table manager configured to store the history read table and control updating of the history read table; and
a read retry controller configured to control the memory device to perform the read retry operation based on the history read table.

5. The storage device of claim 1, wherein the history read table stores a read voltage with which a corresponding read retry operation is to be performed.

6. The storage device of claim 1, wherein the memory controller is configured to check whether the word line is the last programmed word line based on a physical address of the memory cell.

7. The storage device of claim 1, wherein the memory controller is configured to perform the read operation on the group of memory cells in which only some of the memory cells in the group are programed.

8. The storage device of claim 1, wherein the read operation includes a sensing operation of sensing a corresponding data stored in the memory cell and a decoding operation of decoding a result obtained from the sensing operation, and
wherein the memory controller is configured to identify a failure of the decoding operation as the failure of the read operation.

9. The storage device of claim 1, wherein the read retry operation includes a sensing operation of sensing a corresponding data stored in the memory cell and a decoding operation of decoding a result obtained from the sensing operation, and wherein the memory controller is configured to identify a success of the decoding operation as the success of the read retry operation.

10. The storage device of claim 3, wherein the memory controller is further configured to update the history read table in case that a comparison result indicates that a difference between the changed read voltage and the pre-stored read voltage is smaller than a predetermined threshold value.

11. A method for operating a storage device, the method comprising:
performing a read operation on a group of memory cells using a read voltage to read data from a memory cell of the group;
performing, upon a failure of the read operation on the memory cell, a read retry operation to perform another read operation on the memory cell by changing the read voltage based on a history read table that includes information on read voltages;
checking, upon a success of the read retry operation on the memory cell, whether the word line connected to the memory cell is a last programmed word line according to a program order among word lines connected to the group of memory cells; and
updating the history read table or skipping updating of the read retry operation based on the checking.

12. The method of claim 11, wherein the history read table is updated with a changed read value in case that the checking indicates that the word line connected to the memory cell is not the last programmed word line.

13. The method of claim 11, further comprising, comparing a changed read voltage with a pre-stored read voltage that is included in the history read table for use for the read retry operation for the memory cell.

14. The method of claim 13, wherein the history read table is updated with a changed read value in case (1) that the checking indicates that the word line connected to the memory cell is the last programmed word line and (2) that the comparing indicates that a difference between the changed read voltage and the pre-stored read voltage is smaller than a threshold value.

15. The method of claim 13, wherein the updating of the history read table is skipped in case (1) that the checking indicates that the word line connected to the memory cell is the last programmed word line and (2) that the comparing indicates that a difference between the changed read voltage and the pre-stored read voltage is not smaller than a threshold value.

16. The method of claim 11, wherein the storage device includes a memory device including the group of memory cells and a memory controller in communication with the memory device and the method further comprising caching the history read table stored in the memory device to the memory controller.

17. The method of claim 11, wherein the history read table stores, for each of the memory cells, a read voltage with which a corresponding read retry operation is to be performed.

18. The method of claim 11, wherein the checking is performed based on a physical address of the memory cell.

19. The method of claim 11, wherein the read operation is performed on the group of memory cells in which only some of the memory cells in the group are programed.

20. The method of claim 11, wherein the performing of the read operation or the read retry operation includes:
performing a sensing operation of sensing a corresponding data stored in the memory cell; and
performing a decoding operation of decoding a result obtained from the sensing operation.
